(19) United States
(12) Patent Application Publication
(10) Pub. No.: US 2015/0123211 A1
(43) Pub. Date: May 7, 2015

(54) NARROW DIFFUSION BREAK FOR A FIN FIELD EFFECT (FinFET) TRANSISTOR DEVICE

(71) Applicant: GLOBALFOUNDRIES Inc., Grand Cayman (KY)

(72) Inventors: Qi Zhang, Mechanicville, NY (US); Hongliang Shen, Ballston Lake, NY (US); Zhenyu Hu, Clifton Park, NY (US); Andy Wei, Queensbury, NY (US); Zhuangfei Chen, Clifton Park, NY (US); Nicholas V. LiCausi, Watervliet, NY (US)

(73) Assignee: GLOBALFOUNDRIES Inc., Grand Cayman (KY)

(21) Appl. No.: 14/070,607

(22) Filed: Nov. 4, 2013

(51) Int. Cl. H01L 27/088; H01L 21/02; H01L 21/324; H01L 21/311; H01L 21/762; H01L 21/8234; H01L 21/306

(52) U.S. Cl. CPC H01L 27/0886; H01L 21/823431; H01L 21/02532; H01L 21/02252; H01L 21/0223; H01L 21/30604; H01L 21/31111; H01L 21/823481; H01L 21/76205; H01L 21/324
USPC 257/401; 438/283

(57) ABSTRACT

Approaches for providing a narrow diffusion break in a fin field effect transistor (FinFET) device are disclosed. Specifically, the FinFET device is provided with a set of fins formed from a substrate, and an opening formed through the set of fins, the opening oriented substantially perpendicular to an orientation of the set of fins. This provides a FinFET device capable of achieving cross-the-fins insulation with an opening size that is adjustable from approximately 20-30 nm.

### BACKGROUND

1. Technical Field

This invention relates generally to the field of semiconductors and, more particularly, to manufacturing approaches used in forming a diffusion break during processing of a FinFET device.

2. Related Art

A typical integrated circuit (IC) chip includes a stack of several levels or sequentially formed layers of shapes. Each layer is stacked or overlaid on a prior layer and patterned to form the shapes that define devices (e.g., field effect transistors (FETs)) and connect the devices into circuits. In a typical state of the art complementary insulated gate FET process, such as what is normally referred to as CMOS, layers are formed on a wafer to form the devices on a surface of the wafer. Further, the surface may be the surface of a silicon layer on a silicon on insulator (SOI) wafer. A simple FET is formed by the intersection of two shapes, a gate layer rectangle on a silicon island formed from the silicon surface layer. Each of these layers of shapes, also known as mask levels or layers, may be created or printed optically through well-known photolithographic masking, developing, and level definition (e.g., etching, implanting, deposition, etc.).

The fin-shaped field effect transistor (FinFET) is a transistor design that attempts to overcome the issues of short-channel effect encountered by deep submicron transistors, such as drain-induced barrier lowering (DIBL). Such effects make it harder for the voltage on a gate electrode to deplete the channel underneath and stop the flow of carriers through the channel—in other words, to turn the transistor off. By raising the channel above the surface of the wafer instead of creating the channel just below the surface, it is possible to wrap the gate around all but one of its sides, providing much greater electrostatic control over the carriers within it.

With operation voltages running lower, and transistor density higher for the emerging FinFET technologies (i.e., 14 nm and smaller), fabricating a super narrow diffusion break (e.g., opening size 20˜30 nm) is becoming more and more meaningful. However, traditional insulation approaches like shallow trench insulation (STI) are facing great technical difficulties in almost every aspect. One major limitation arises during lithography printing of ultra small spaces more narrow than 32 nm or lines narrower than 40 nm before the maturity of EUV patterning technology. It is difficult to achieve etch straight profile and high aspect ratio trench, gap fill void free filling, and uniform chemical mechanical planarization (CMP) within wafer.

### SUMMARY

In general, approaches for providing a narrow diffusion break in a fin field effect transistor (FinFET) device are provided. Specifically, the FinFET device is provided with a set of fins formed from a substrate, and an opening formed through the set of fins, the opening oriented substantially perpendicular to an orientation of the set of fins. This provides a FinFET device capable of achieving cross-the-fins insulation with an opening size that is adjustable from approximately 20-30 nm.

One aspect of the present invention includes a method for forming a fin field effect transistor (FinFET) device, the method comprising: forming a set of fins from a substrate; and forming an opening through the set of fins, the opening oriented substantially perpendicular to an orientation of the set of fins.

Another aspect of the present invention includes a method for forming a narrow diffusion break in a fin field effect transistor (FinFET) device, the method comprising: forming a set of fins from a substrate; and forming an opening through the set of fins, the opening oriented substantially perpendicular to an orientation of the set of fins.

Yet another aspect of the present invention includes a fin field effect transistor (FinFET) device comprising: a set of fins formed from a substrate; and an opening formed through the set of fins, the opening oriented substantially perpendicular to an orientation of the set of fins.

### BRIEF DESCRIPTION OF THE DRAWINGS

These and other features of this invention will be more readily understood from the following detailed description of the various aspects of the invention taken in conjunction with the accompanying drawings in which:

FIG. 1(a) shows a cross-sectional view, along a first direction, of formation of a FinFET device according to illustrative embodiments;

FIG. 1(b) shows a cross-sectional view, along a second direction that is perpendicular to the first direction shown in FIG. 1(a), of formation of the FINFET device according to illustrative embodiments;

FIG. 2(a) shows a cross-sectional view, along the first direction, of formation of an opening in a hardmask formed over the FINFET device according to illustrative embodiments;

FIG. 2(b) shows a cross-sectional view, along the second direction, of formation of the opening in the hardmask formed over the FINFET device according to illustrative embodiments;

FIG. 3(a) shows a cross-sectional view, along the first direction, of a fin cut oxide reactive ion etch (RIE) according to illustrative embodiments;

FIG. 3(b) shows a cross-sectional view, along the second direction, of the fin cut oxide RIE according to illustrative embodiments;

FIG. 4(a) shows a cross-sectional view, along the first direction, of a hardmask and silicon trench etch according to illustrative embodiments;

FIG. 4(b) shows a cross-sectional view, along the second direction, of the hardmask and silicon trench etch according to illustrative embodiments;

FIG. 5(a) shows a cross-sectional view, along the first direction, of a selective epitaxial silicon growth in the trench according to illustrative embodiments;

FIG. 5(b) shows a cross-sectional view, along the second direction, of the selective epitaxial silicon growth in the trench according to illustrative embodiments;

FIG. 6(a) shows a cross-sectional view, along the first direction, of a silicon etch to expose the fin sidewall in the trench according to illustrative embodiments;

FIG. 6(b) shows a cross-sectional view, along the second direction, of the silicon etch to expose the fin sidewall in the trench according to illustrative embodiments;

FIG. 7(a) shows a cross-sectional view, along the first direction, of an oxide CMP that stops on a remaining fin hardmask according to illustrative embodiments;

FIG. 7(b) shows a cross-sectional view, along the second direction, of the oxide CMP that stops on a remaining fin hardmask according to illustrative embodiments;

FIG. 8(a) shows a cross-sectional view, along the first direction, of a STI deglaze according to illustrative embodiments;

FIG. 8(b) shows a cross-sectional view, along the second direction, of the STI deglaze according to illustrative embodiments;

FIG. 9(a) shows a cross-sectional view, along the first direction, of a nitride hardmask strip according to illustrative embodiments;

FIG. 9(b) shows a cross-sectional view, along the second direction, of the nitride hardmask strip according to illustrative embodiments;

FIG. 10(a) shows a cross-sectional view, along the first direction, of an oxide buffer CMP that stops on the oxide and nitride according to illustrative embodiments;

FIG. 10(b) shows a cross-sectional view, along the second direction, of the oxide buffer CMP that stops on the oxide and nitride according to illustrative embodiments;

FIG. 11(a) shows a cross-sectional view, along the first direction, of a nitride selective RIE according to illustrative embodiments;

FIG. 11(b) shows a cross-sectional view, along the second direction, of the nitride selective RIE according to illustrative embodiments;

FIG. 12(a) shows a cross-sectional view, along the first direction, of a fin reveal according to illustrative embodiments;

FIG. 12(b) shows a cross-sectional view, along the second direction, of the fin reveal according to illustrative embodiments;

FIG. 13(a) shows a cross-sectional view, along the first direction, of an inner spacer deposition according to illustrative embodiments;

FIG. 13(b) shows a cross-sectional view, along the second direction, of the inner spacer deposition according to illustrative embodiments;

FIG. 14(a) shows a cross-sectional view, along the first direction, of a spacer RIE to the inner spacer to expose the fin tops/STI oxide in the cavity according to illustrative embodiments;

FIG. 14(b) shows a cross-sectional view, along the second direction, of the spacer RIE to the inner spacer to expose the fin tops/STI oxide in the cavity according to illustrative embodiments;

FIG. 15(a) shows a cross-sectional view, along the first direction, of a silicon etch to expose the fin sidewall in the trench according to illustrative embodiments;

FIG. 15(b) shows a cross-sectional view, along the second direction, of the silicon etch to expose the fin sidewall in the trench according to illustrative embodiments;

FIG. 16(a) shows a cross-sectional view, along the first direction, of a thermal oxidation to the trench according to illustrative embodiments;

FIG. 16(b) shows a cross-sectional view, along the second direction, of the thermal oxidation to the trench according to illustrative embodiments;

FIG. 17(a) shows a cross-sectional view, along the first direction, of a high density plasma (HDP) oxide deposition according to illustrative embodiments;

FIG. 17(b) shows a cross-sectional view, along the second direction, of the HDP oxide deposition according to illustrative embodiments;

FIG. 18(a) shows a cross-sectional view, along the first direction, of an oxide CMP stop on the spacer and the remaining fin hardmask according to illustrative embodiments;

FIG. 18(b) shows a cross-sectional view, along the second direction, of the oxide CMP stop on the spacer and the remaining fin hardmask according to illustrative embodiments;

FIG. 19(a) shows a cross-sectional view, along the first direction, of a STI deglaze according to illustrative embodiments;

FIG. 19(b) shows a cross-sectional view, along the second direction, of the STI deglaze according to illustrative embodiments;

FIG. 20(a) shows a cross-sectional view, along the first direction, of a hardmask and spacer strip according to illustrative embodiments;

FIG. 20(b) shows a cross-sectional view, along the second direction, of the hardmask and spacer strip according to illustrative embodiments;

FIG. 21(a) shows a cross-sectional view, along the first direction, of an oxide buffer CMP stop on oxide and nitride according to illustrative embodiments;

FIG. 21(b) shows a cross-sectional view, along the second direction, of the oxide buffer CMP stop on oxide and nitride according to illustrative embodiments;

FIG. 22(a) shows a cross-sectional view, along the first direction, of a nitride selective RIE according to illustrative embodiments;

FIG. 22(b) shows a cross-sectional view, along the second direction, of the nitride selective RIE according to illustrative embodiments;

FIG. 23(a) shows a cross-sectional view, along the first direction, of a fin reveal according to illustrative embodiments;

FIG. 23(b) shows a cross-sectional view, along the second direction, of the fin reveal according to illustrative embodiments;

FIG. 24(a) shows a cross-sectional view, along the first direction, of an in-situ radical assisted deposition (iRAD) of oxide according to illustrative embodiments;

FIG. 24(b) shows a cross-sectional view, along the second direction, of the iRAD of oxide according to illustrative embodiments;

FIG. 25(a) shows a cross-sectional view, along the first direction, of an oxide RIE to form an inner oxide spacer according to illustrative embodiments;

FIG. 25(b) shows a cross-sectional view, along the second direction, of the oxide RIE to form the inner oxide spacer according to illustrative embodiments;

FIG. 26(a) shows a cross-sectional view, along the first direction, of a trench etch according to illustrative embodiments;

FIG. 26(b) shows a cross-sectional view, along the second direction, of the trench etch according to illustrative embodiments;

FIG. 27(a) shows a cross-sectional view, along the first direction, of a thermal oxidation according to illustrative embodiments;

FIG. 27(b) shows a cross-sectional view, along the second direction, of the thermal oxidation according to illustrative embodiments;

FIG. 28(a) shows a cross-sectional view, along the first direction, of a high density plasma oxide deposition according to illustrative embodiments;

FIG. 28(b) shows a cross-sectional view, along the second direction, of the high density plasma oxide deposition according to illustrative embodiments;

FIG. 29(a) shows a cross-sectional view, along the first direction, of an oxide CMP stop on the pad nitride according to illustrative embodiments;

FIG. 29(b) shows a cross-sectional view, along the second direction, of the oxide CMP stop on the pad nitride according to illustrative embodiments;

FIG. 30(a) shows a cross-sectional view, along the first direction, of a mandrel deposition according to illustrative embodiments; and

FIG. 30(b) shows a cross-sectional view, along the second direction, of the mandrel deposition according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Also, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g. a second layer, wherein intervening elements, such as an interface structure, e.g. interface layer, may be present between the first element and the second element.

As used herein, “depositing” may include any now known or later developed techniques appropriate for the material to be deposited including, but not limited to, for example: chemical vapor deposition (CVD), low-pressure CVD (LPCVD), plasma-improved CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

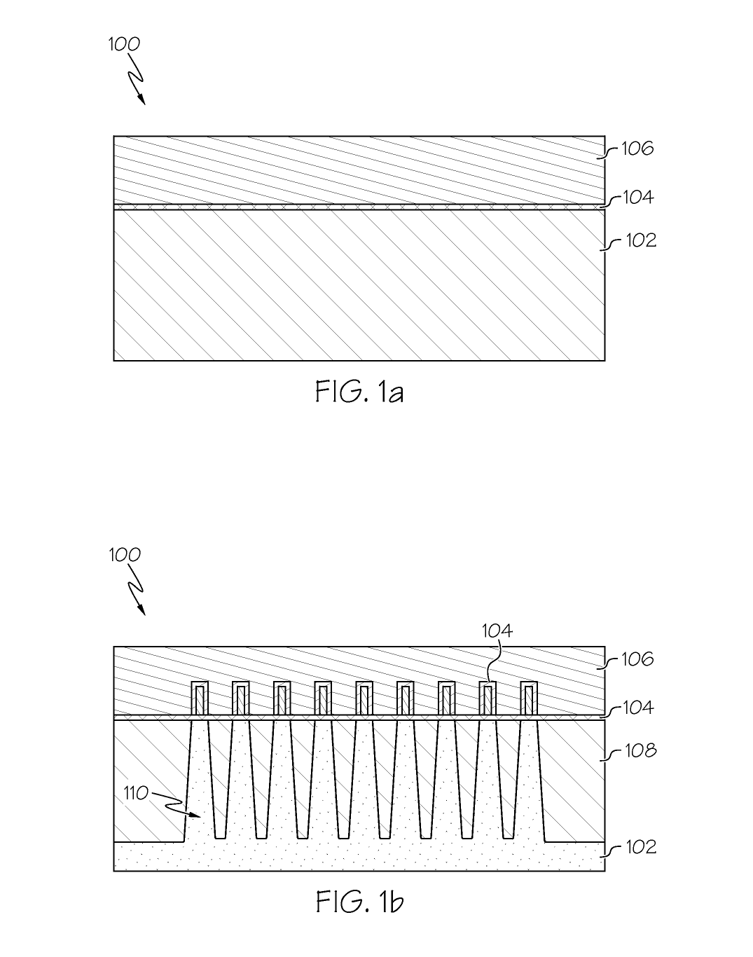

With reference now to the figures, FIG. 1(a) shows a cross-sectional view, along a first direction (e.g., ‘x’ direction), of a device 100 (e.g., a FinFET) according to an embodiment of the invention, and FIG. 1(b) shows a cross-sectional view, along a second direction (e.g., ‘y’ direction) perpendicular to the first direction, of device 100. Device 100 comprises a substrate 102, a pad layer 104 (e.g., nitride) formed over substrate 102, a hard mask 106 (e.g., oxide) formed over pad layer 104, and a hard mask 106 having a thickness of approximately 85-90 nm. In one embodiment, pad layer 104 may be composed of nitride formed utilizing a conventional deposition process such as CVD or plasma-assisted CVD. As best shown in FIG. 1(b), device 100 further comprises a shallow trench isolation (STI) layer 108, and a set of fins 110 formed from substrate 102, wherein pad layer 104 is formed over STI layer 108 and fins 110, to a thickness of approximately 40 nm.

The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type semiconductor layers formed thereover or associated therewith. A portion or entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped, or contain doped regions and undoped regions therein. The semiconductor substrate may contain regions with strain and regions without strain therein, or contain regions of tensile strain and compressive strain.

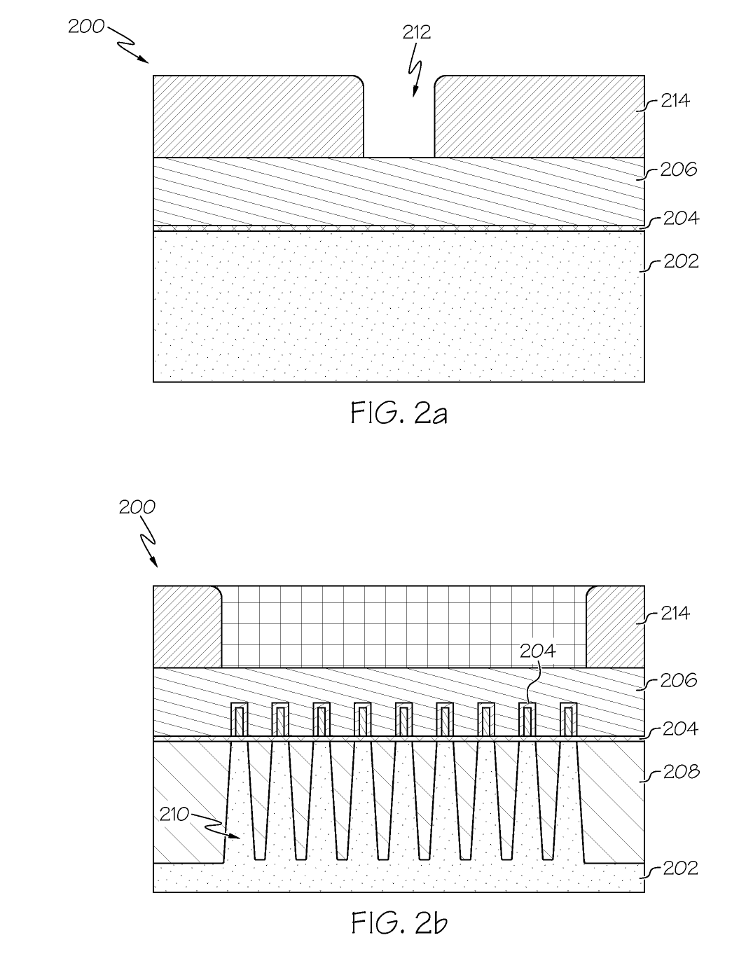

Next, as shown in FIGS. 2(a)-2(b), an opening 212 is formed through an FC mask 214 (e.g., a photoresist mask) selective to hard mask 206. In this embodiment, opening 212 is patterned, for example, using a photo-lithography process or other lithographic process (e.g., electron beam lithography, imprint lithography, etc.), and removed by a suitable etching process including a wet etch, dry etch, plasma etch, and the like.

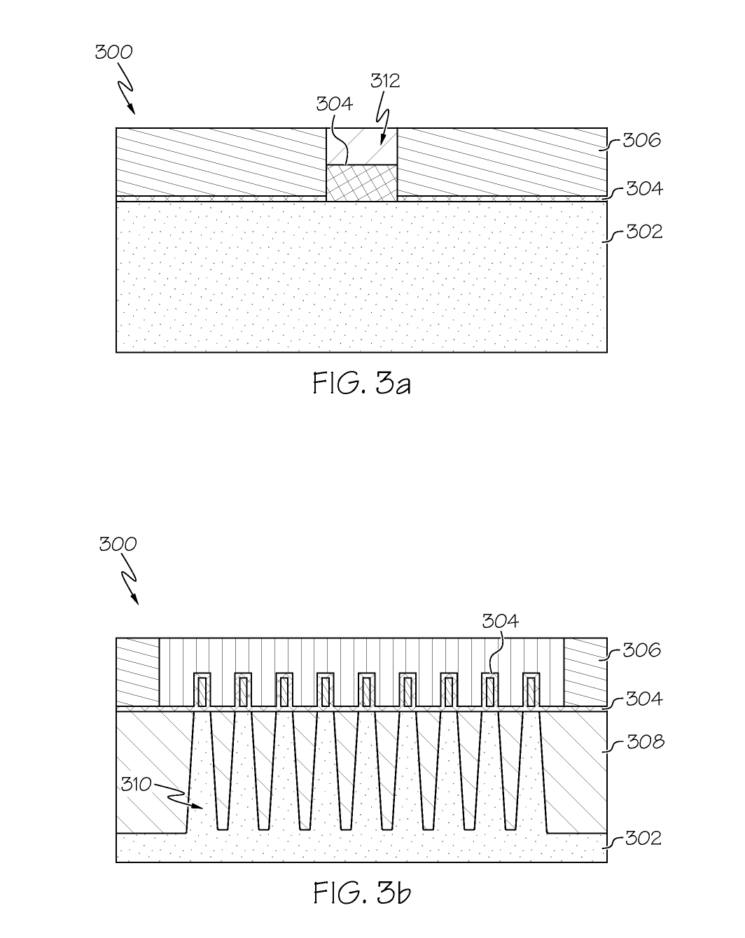

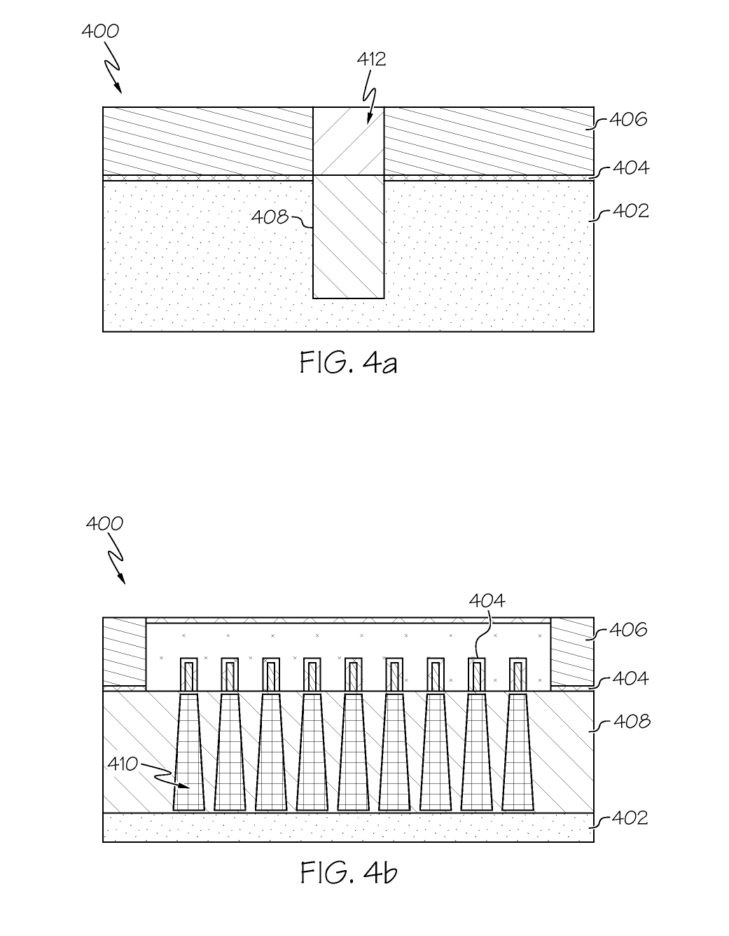

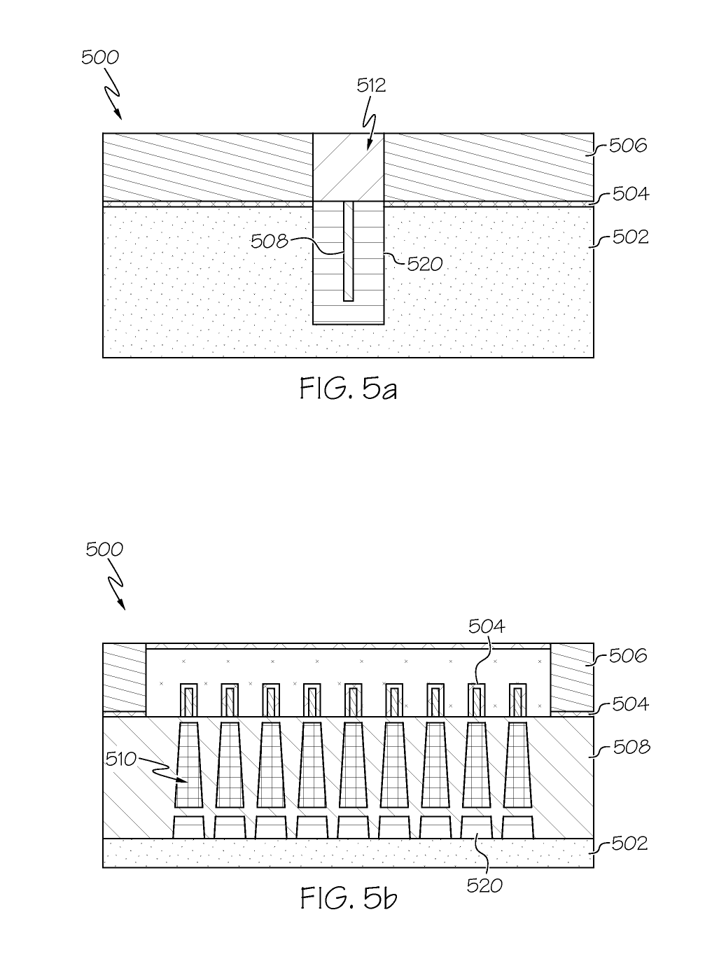

As shown in FIGS. 3(a)-(b), an opening 312 is then extended down into hard mask 306 selective to pad layer 304, and the FC mask is removed. In this embodiment, the section of hard mask 306 left exposed by opening 312 is removed using an oxide RIE with a self-stop on nitride of pad layer 304. As shown in FIGS. 4(a)-(b), pad layer 404 and silicon of fins 410 are then etched in opening 412, followed by a selective epitaxial Si growth, as shown in FIGS. 5(a)-(b). In this embodiment, a silicon layer 520 is formed along the surfaces within opening 512, leaving a narrow opening (i.e., approximately 20-30 nm) within substrate 502.

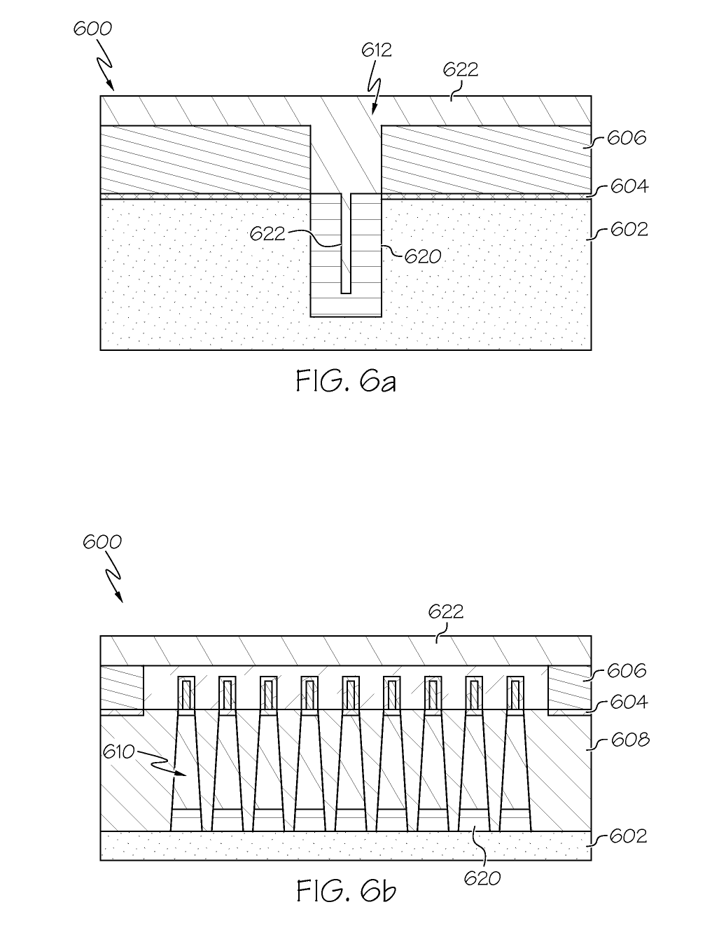

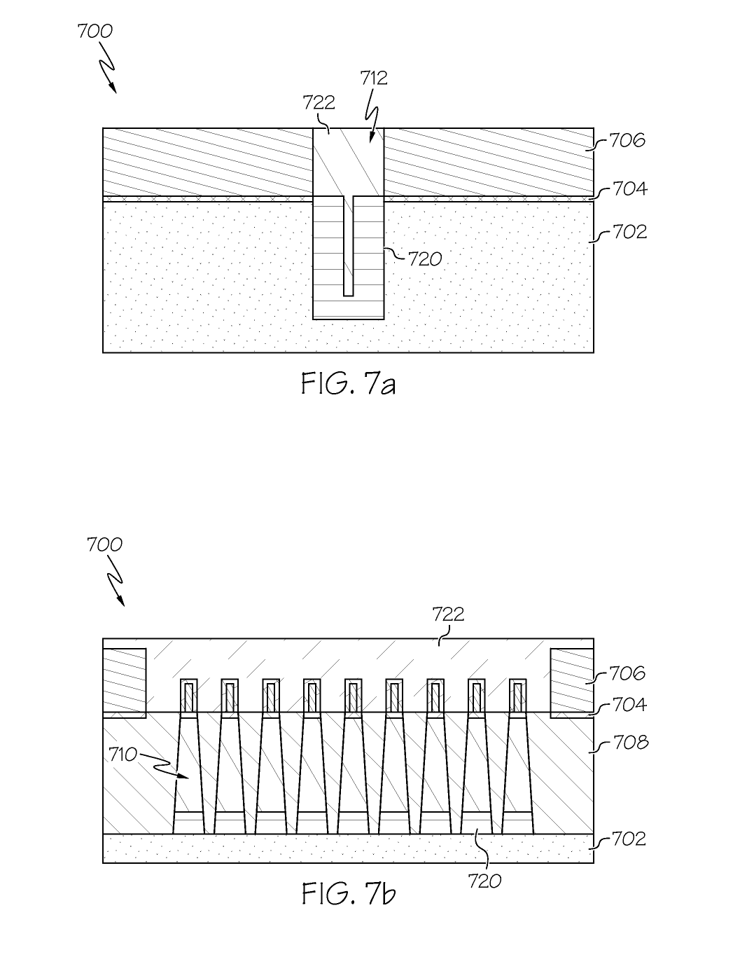

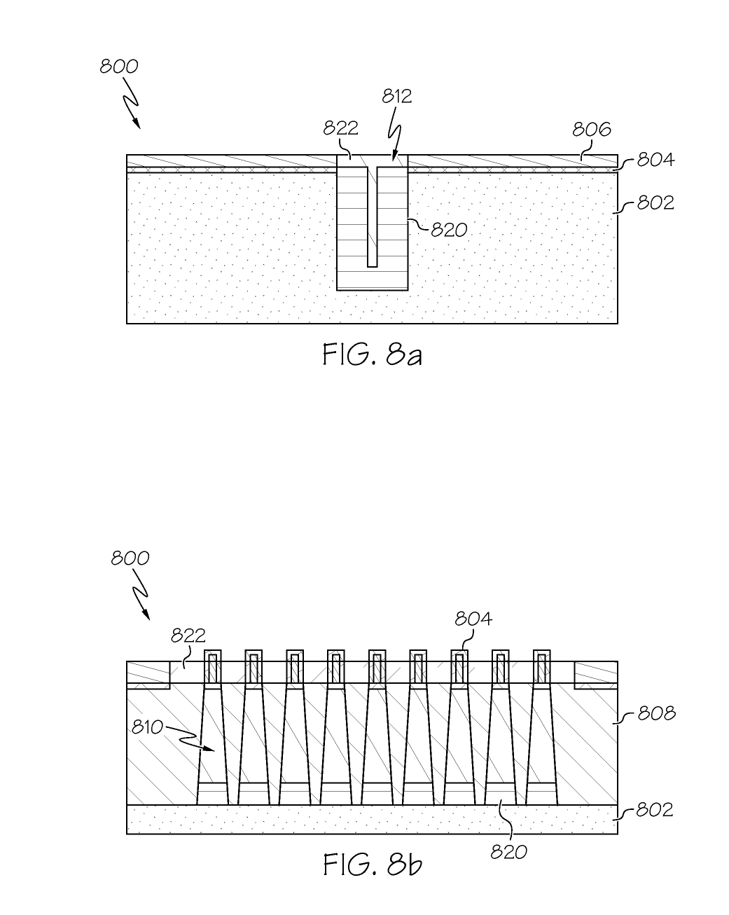

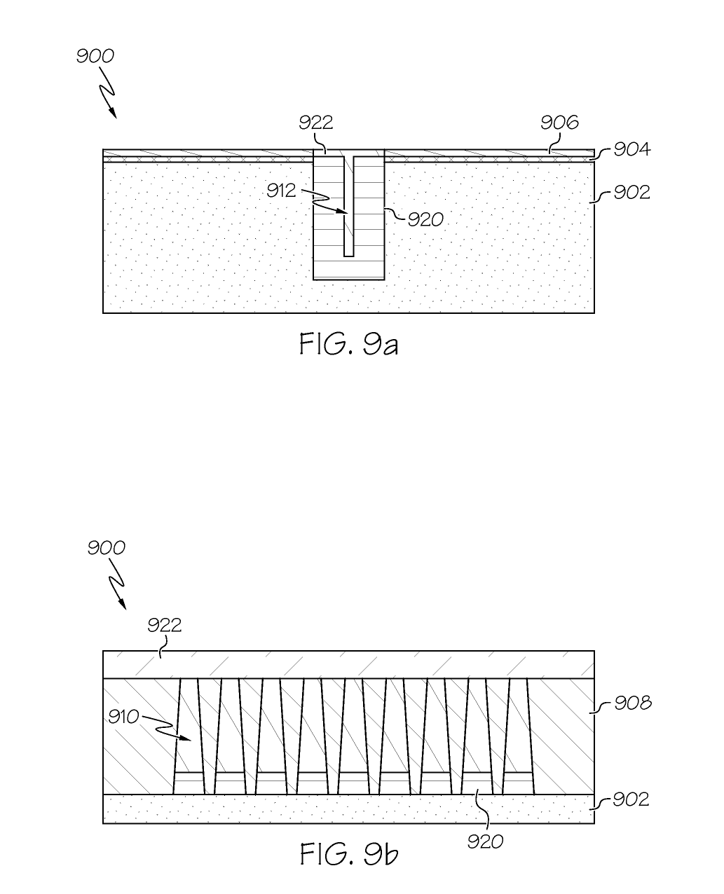

Next, as shown in FIGS. 6(a)-(b), a high density plasma (HDP) oxide 622 is deposited over pad layer 606 and within the narrow opening formed by silicon layer 620, and planarized, as shown in FIGS. 7(a)-(b). In this embodiment, HDP oxide 722 is removed via CMP, which stops on the remaining nitride pad layer 704 over each fin 710. A deglaze (e.g., a wet or dry etch) is then performed, as shown in FIGS. 8(a)-(b), to remove a portion of hard mask 806 and HDP oxide 822, and expose pad layer 804 remaining over fins 810. Pad layer 804 is subsequently removed, as shown in FIGS. 9(a)-(b).

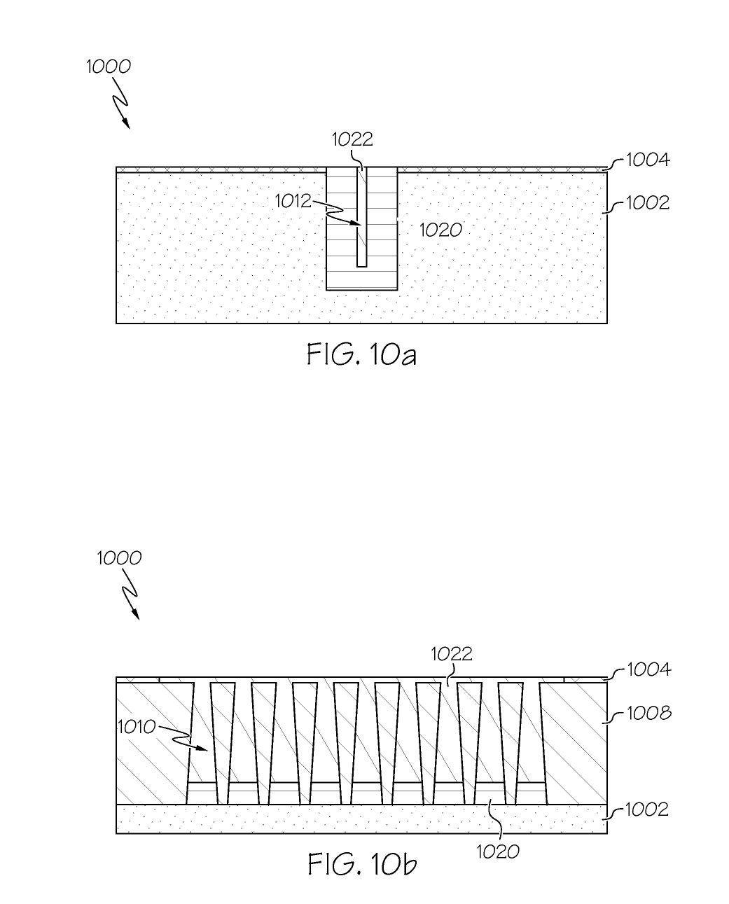

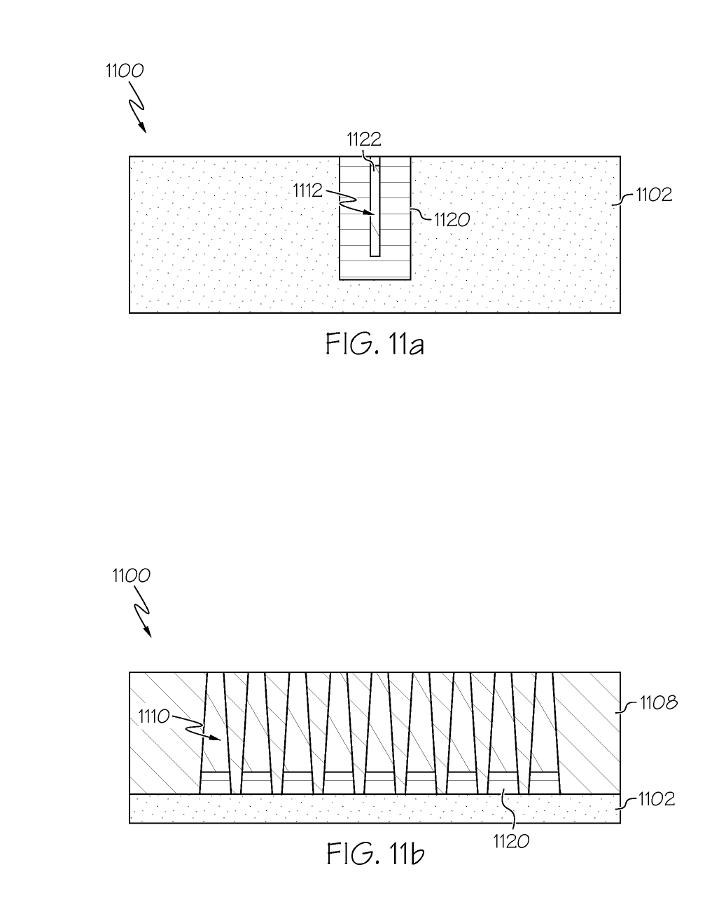

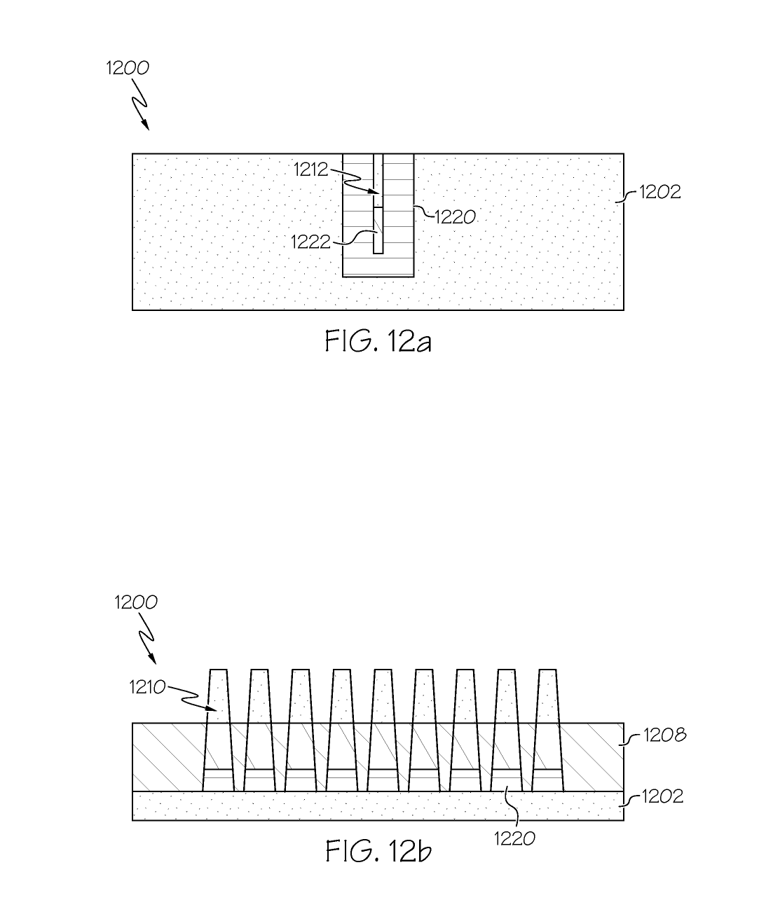

Next, an oxide buffer CMP that stops on HDP oxide 1022 and pad layer 1004 is performed, as shown in FIGS. 10(a)-(b), followed by a selective RIE to remove pad layer 1104, as shown in FIGS. 11(a)-(b). Finally, as shown in FIGS. 12(a)-(b), a portion of STI 1208 is removed to reveal fins 1210. In this embodiment, opening 1212 is a vertical slit formed through each fin 1210. That is, opening 1212 is oriented substantially perpendicular to an orientation of set of fins 1210.

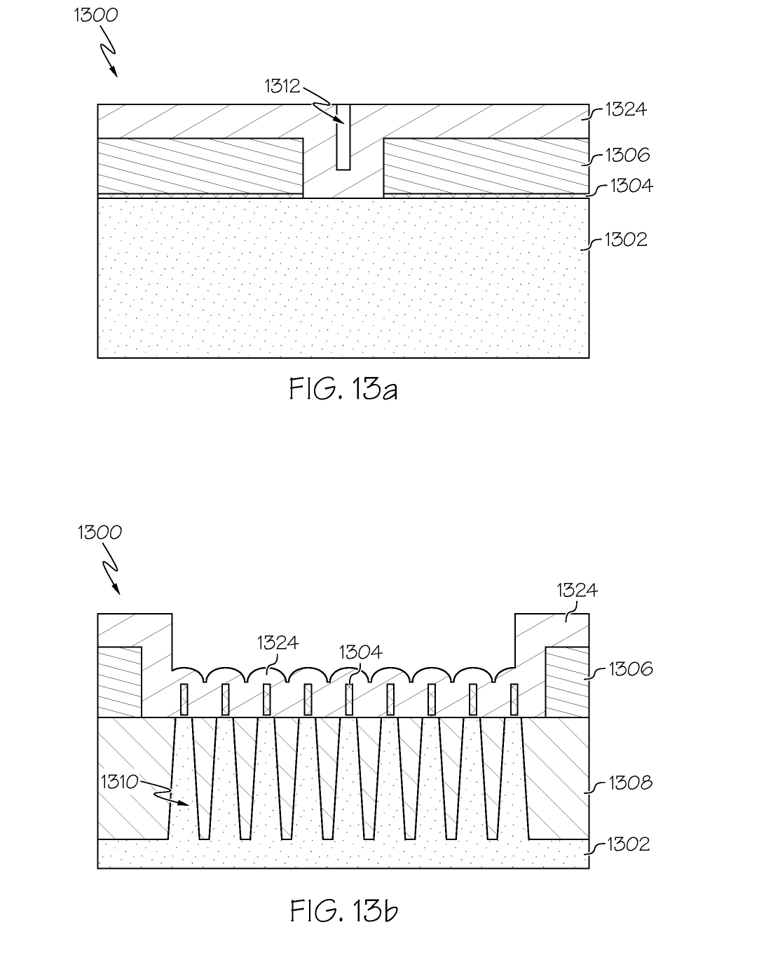

Referring now to FIGS. 13(a)-(b), another embodiment for forming a narrow diffusion break for a FinFET device will be shown and described. In this embodiment, initial processing of the FinFET device is similar to that shown in FIGS. 1-3 and, therefore, the details are not repeated again here for the sake of brevity. FIG. 13(a) shows a cross-sectional view, along a first direction (e.g., ‘x’ direction), of a device 1300 (e.g., a FinFET), and FIG. 13(b) shows a cross-sectional view, along a second direction (e.g., ‘y’ direction) perpendicular to the first direction, of device 1300. In this embodiment, an inner spacer 1324 (e.g., nitride) is initially deposited over device 1300, to a thickness of approximately 15-22 nm, and forms along each surface of opening 1312, as well as over each fin 1310.

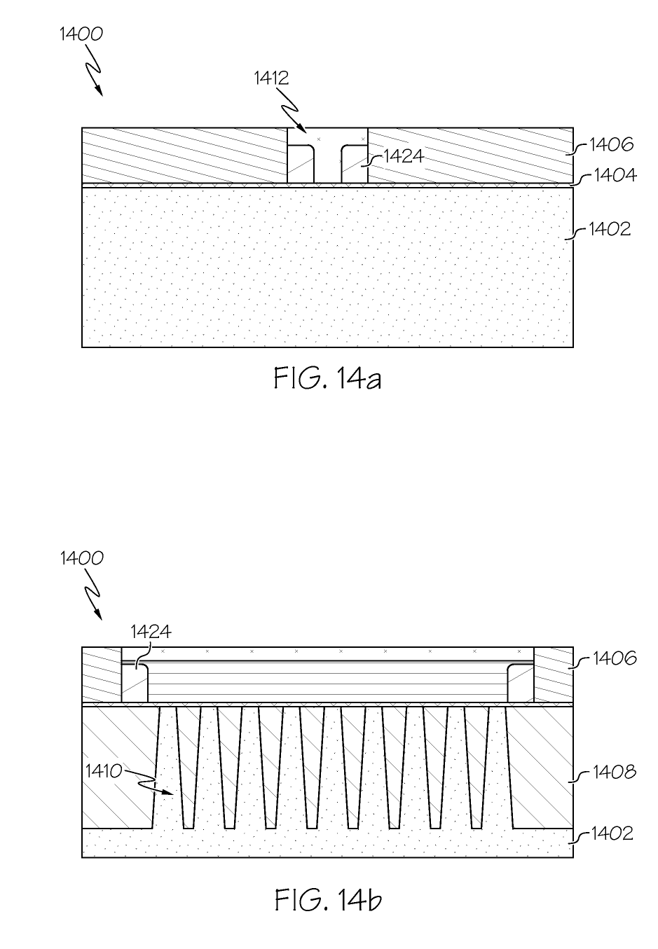

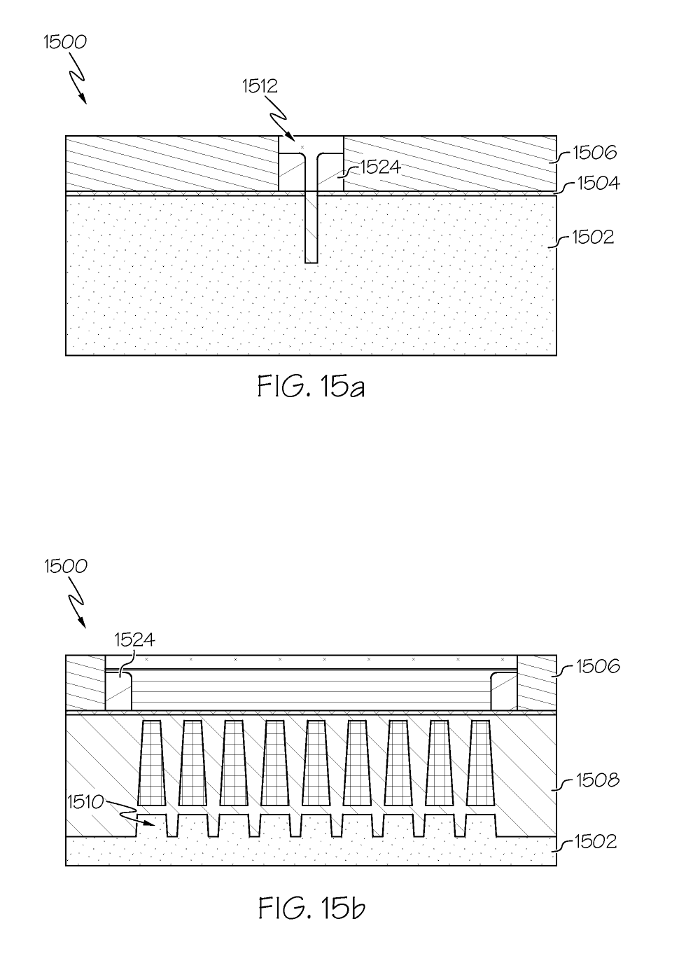

Next, as shown in FIGS. 14(a)-(b), a nitride RIE to inner spacer 1424 is performed to pattern inner spacer 1424 and to expose fins 1410 and STI layer 1408 within opening 1412, and opening 1412 is then extended down into the substrate, as shown in FIGS. 15(a)-(b). In this embodiment, a silicon etch to a target depth of approximately 60 nm is performed to expose the fin sidewall in opening 1512.

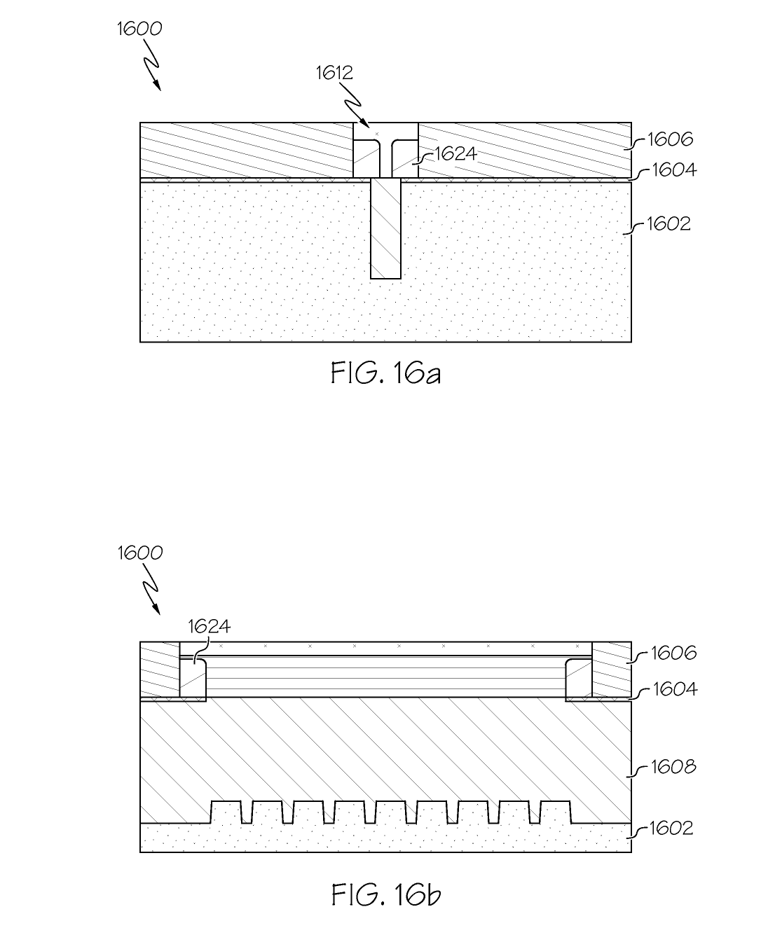

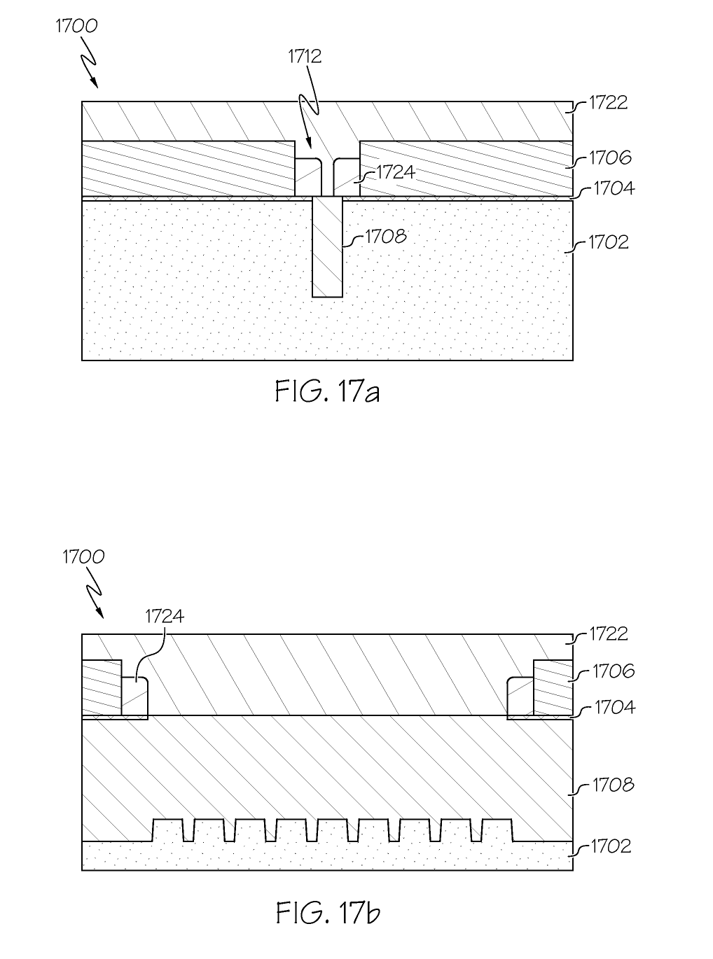

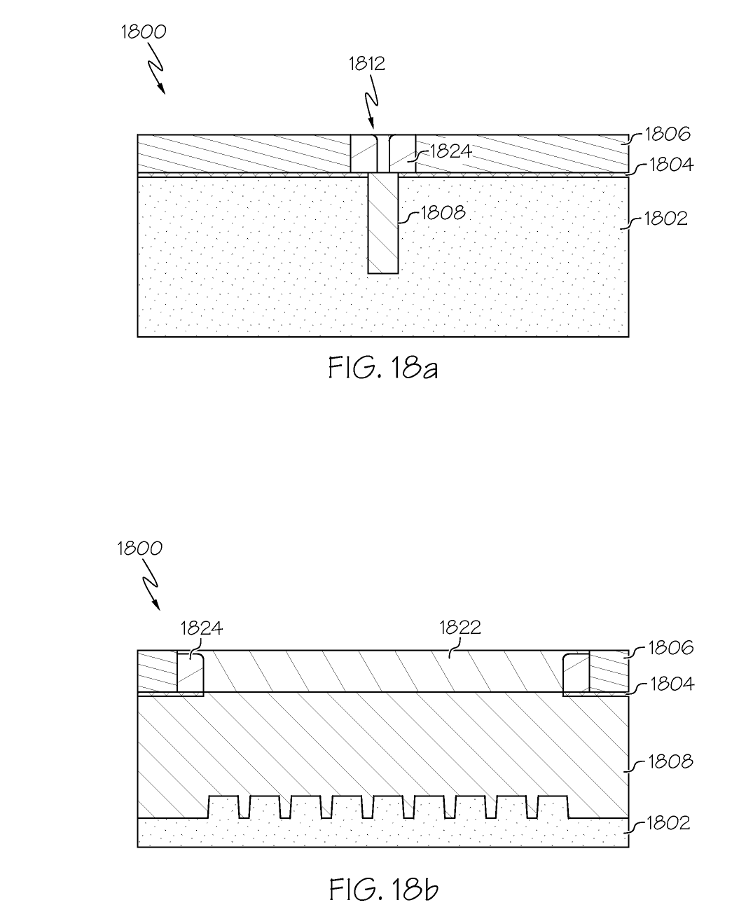

A thermal oxidation is then performed, as shown in FIGS. 16(a)-(b), resulting in a wider opening 1612 within substrate 1602 below inner spacer 1624. In one non-limiting embodiment, the final width of opening 1612 at the top is approximately 30-34 nm, while the bottom is approximately 20 nm. HDP oxide 1722 is then formed over device 1700, as shown in FIGS. 17(a)-(b), followed by an oxide CMP of hardmask 1806 that stops on inner spacer 1824, as shown in FIGS. 18(a)-(b).

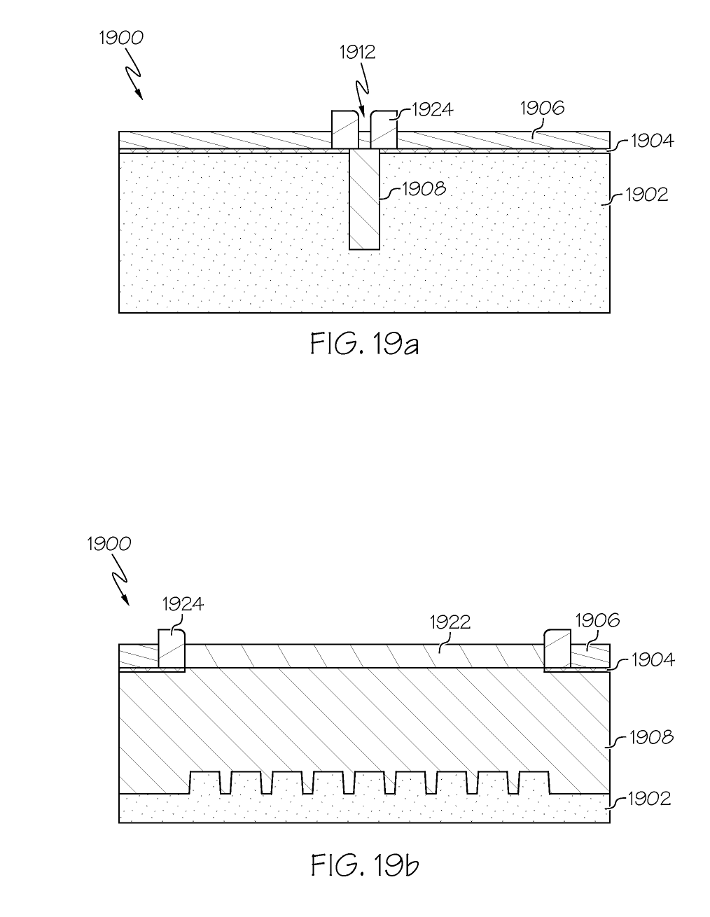

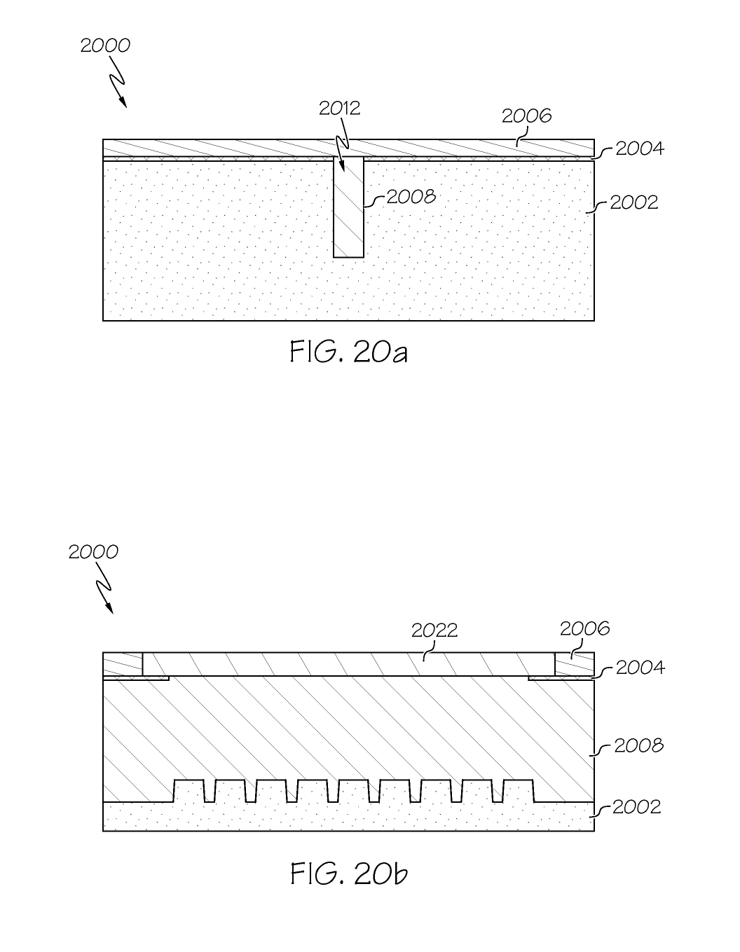

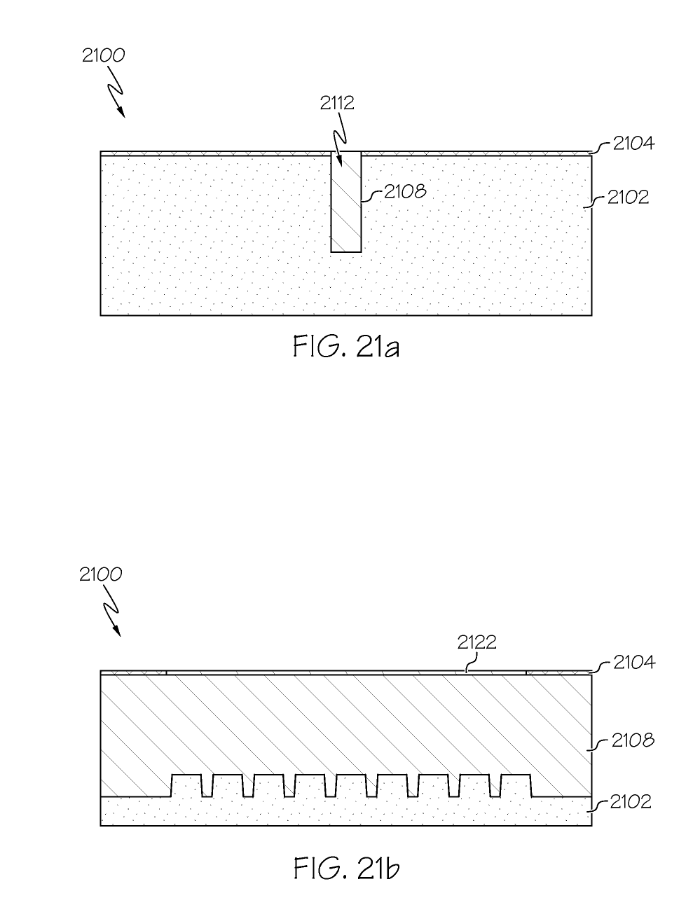

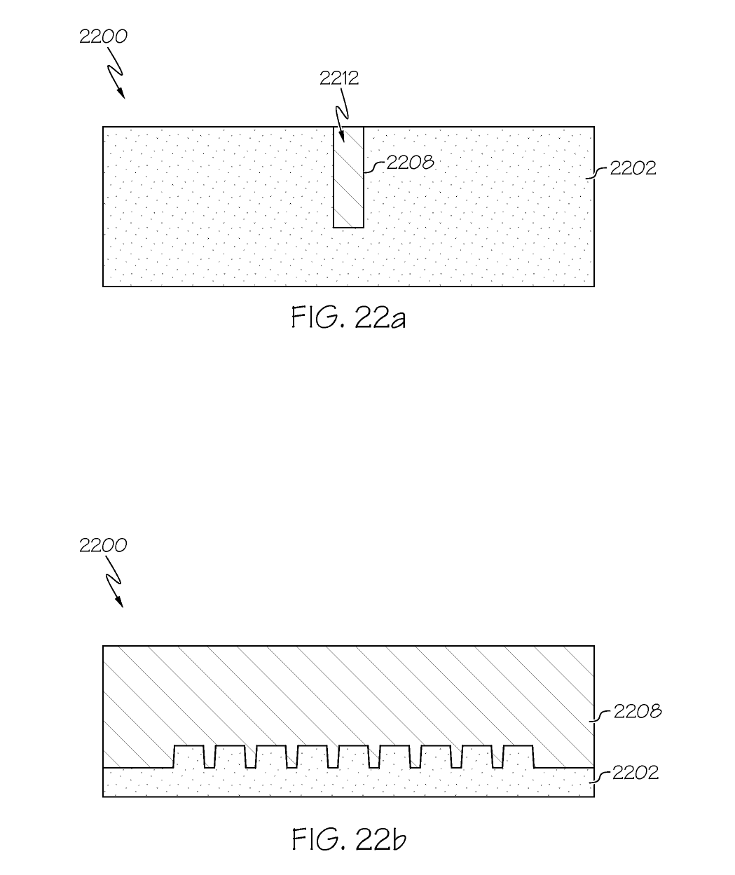

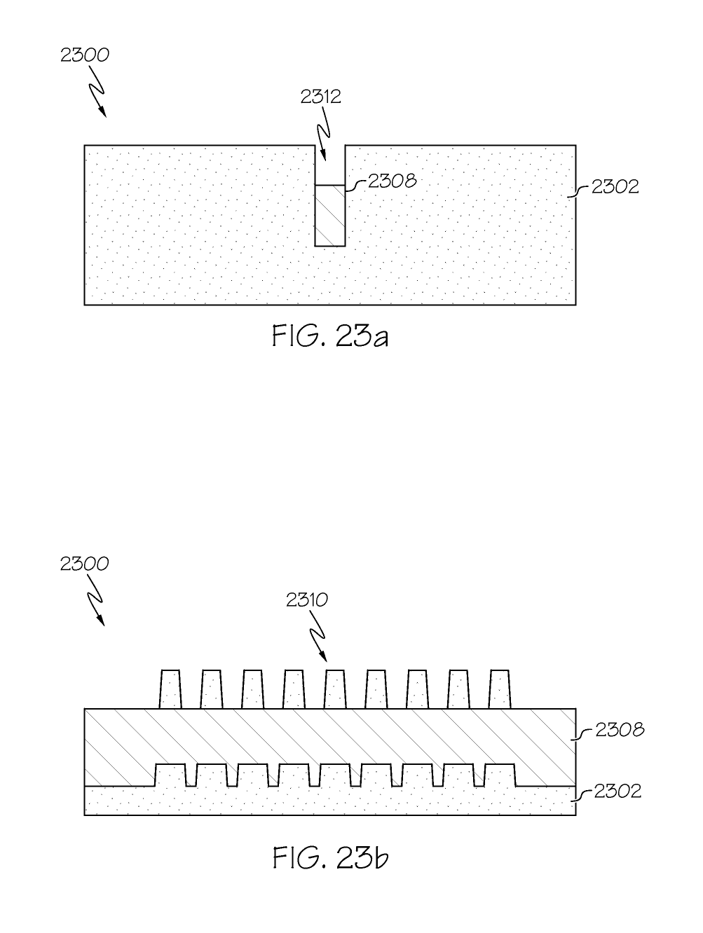

Next, as shown in FIGS. 19(a)-(b), a deglaze is performed to further remove a portion of hard mask 1906 and HDP oxide 1922, and to expose inner spacer 1924, which is subsequently removed, as shown in FIGS. 20(a)-(b). An oxide buffer CMP that stops on pad layer 2104 is then performed, as shown in FIGS. 21(a)-(b), followed by a nitride selective RIE to remove pad layer 2104, as shown in FIGS. 22(a)-(b). Finally, a portion of STI 2308 is removed to reveal fins 2310, as shown in FIGS. 23(a)-(b), and wafer processing continues.

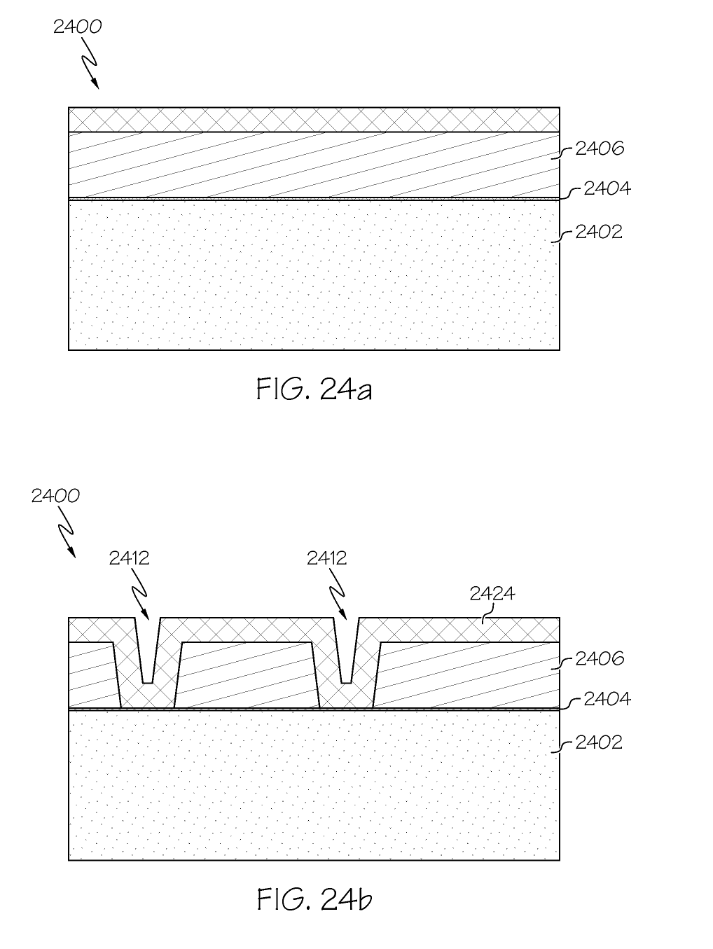

Referring now to FIGS. 24(a)-(b) another embodiment for forming a narrow diffusion break for a FinFET device will be shown and described. In this embodiment, initial processing of the FinFET device is similar to that resulting in the device shown in FIG. 13 and, therefore, the details are not repeated again here for the sake of brevity. FIG. 24(a) shows a cross-sectional view, along a first direction (e.g., ‘x’ direction), of a device 2400 (e.g., a FinFET), and FIG. 24(b) shows a cross-sectional view, along a second direction (e.g., ‘y’ direction) perpendicular to the first direction, of device 2400. In this embodiment, an inner spacer 2424 (e.g., nitride) is initially deposited over device 2400, including along each surface of openings 2412. In this embodiment, inner spacer 2424 is formed using an in-situ radical assisted deposition (iRAD) of oxide to a thickness of approximately 24-27 nm.

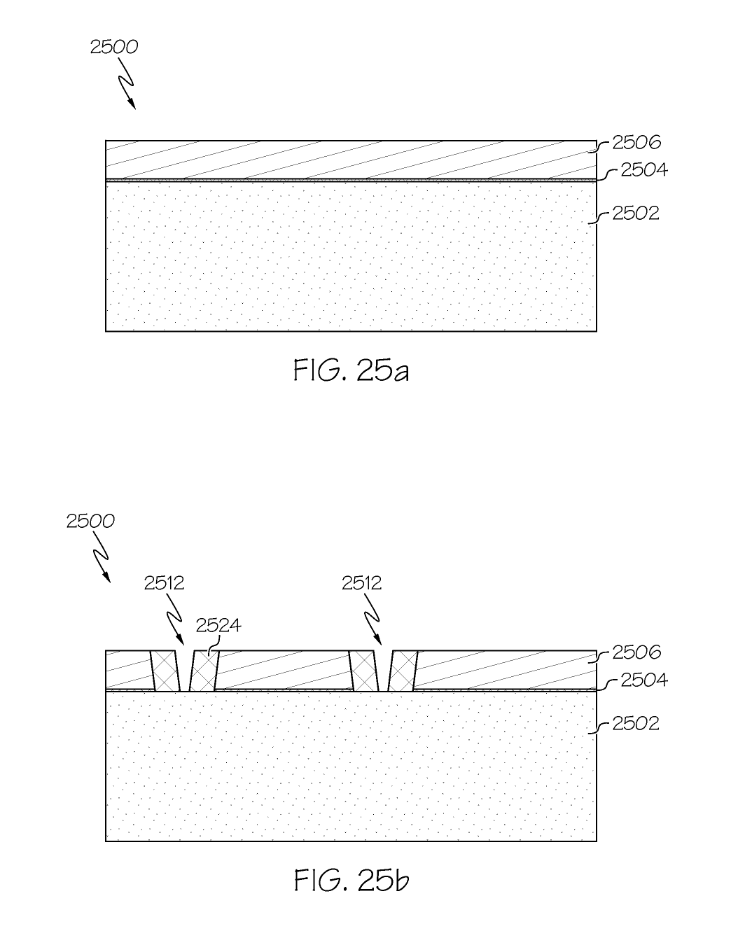

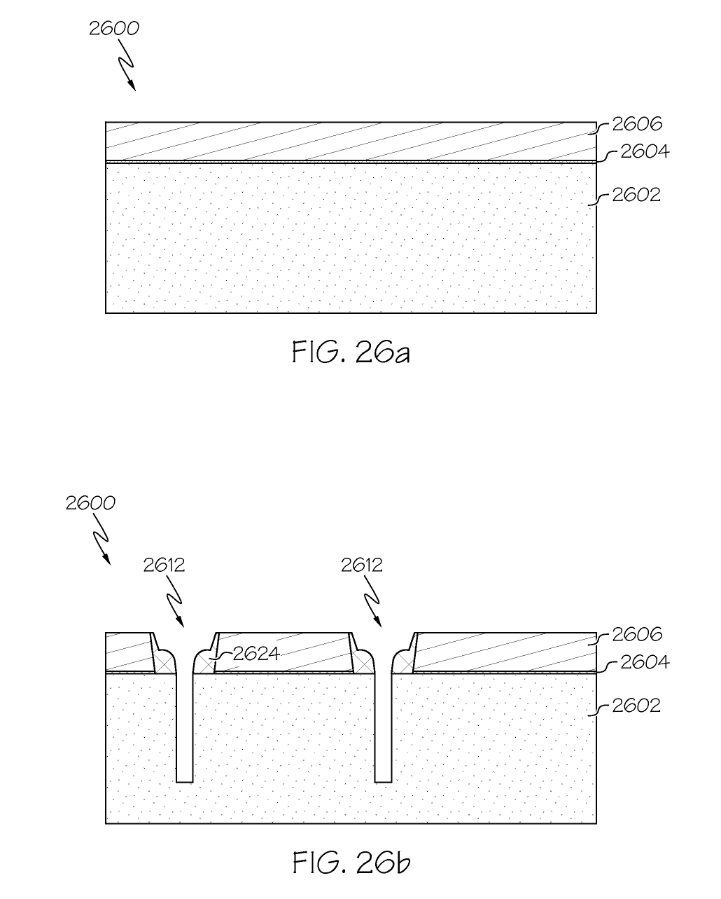

Next, as shown in FIGS. 25(a)-(b), an oxide RIE to inner spacer 2524 is performed to pattern inner spacer 2524 within openings 2512, and openings 2512 are then extended down into the substrate, as shown in FIGS. 26(a)-(b). In this embodiment, a silicon etch is performed to a target depth of approximately 70 nm, with a top critical dimension (CD) of approximately 15˜17 nm, and a bottom CD of approximately 10 nm.

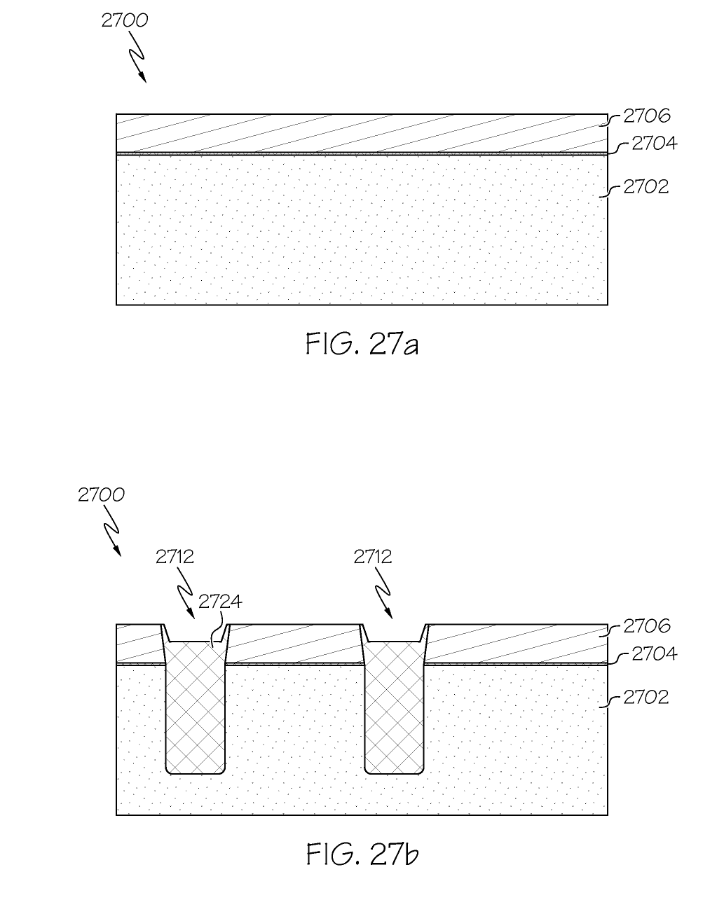

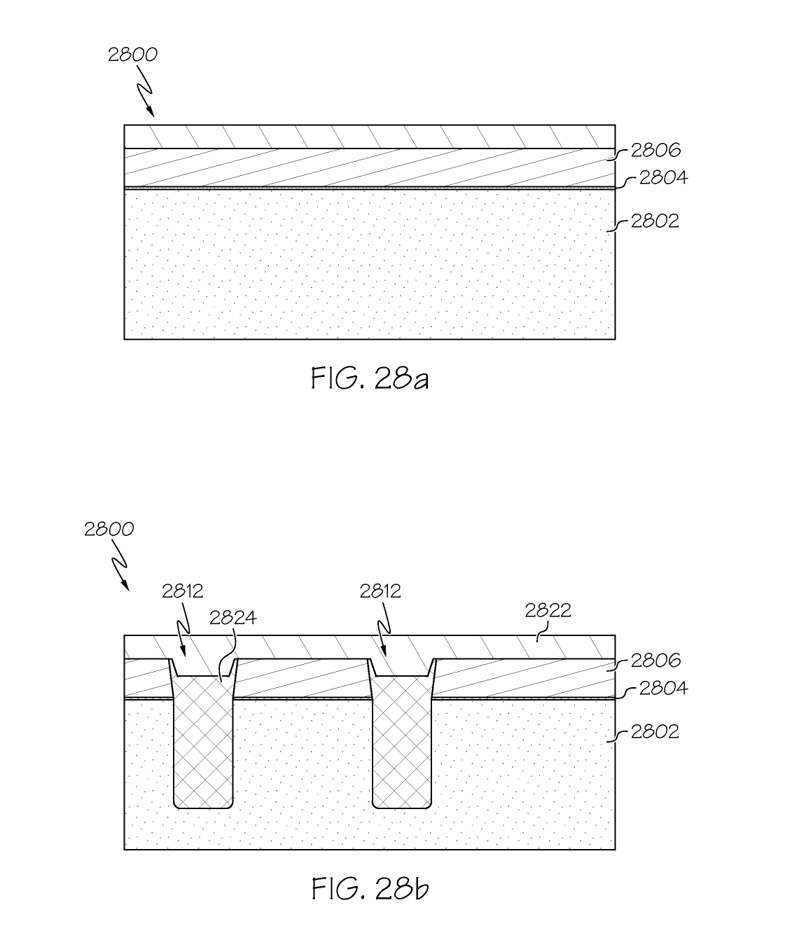

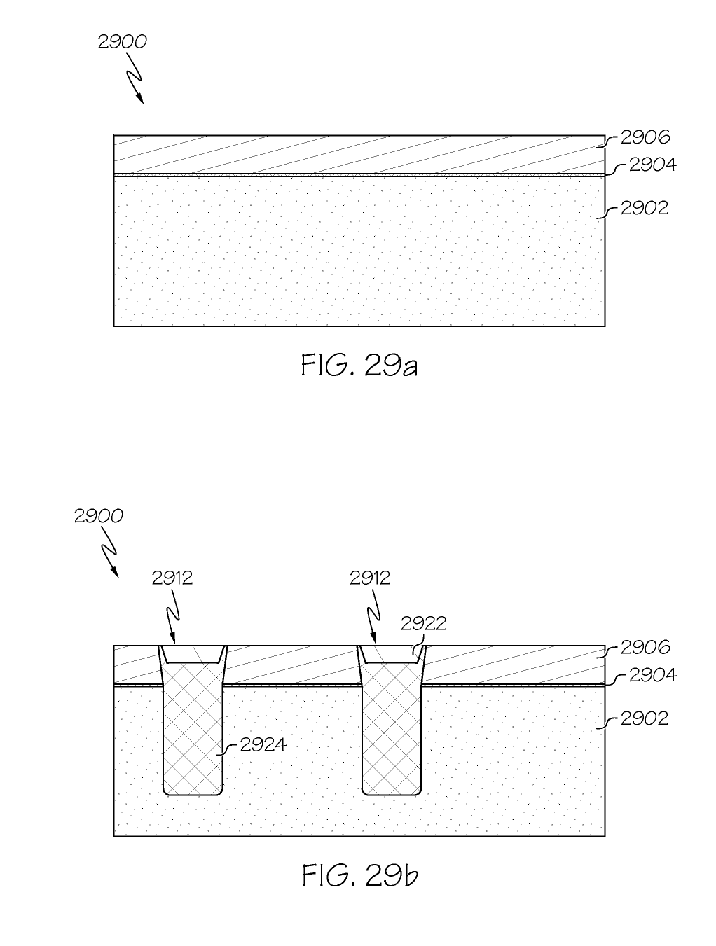

A thermal oxidation is then performed, as shown in FIGS. 27(a)-(b), resulting in a wider opening 2712 within substrate 2702 below inner spacer 2724. In one non-limiting embodiment, the final width of opening 2712 at the top is approximately 30-34 nm, while the bottom is approximately 20 nm. HDP oxide 2822 is then formed over the device, as shown in FIGS. 28(a)-(b), followed by an oxide CMP of HDP oxide 2822 that stops on hard mask 2906, as shown in FIGS. 29(a)-(b).

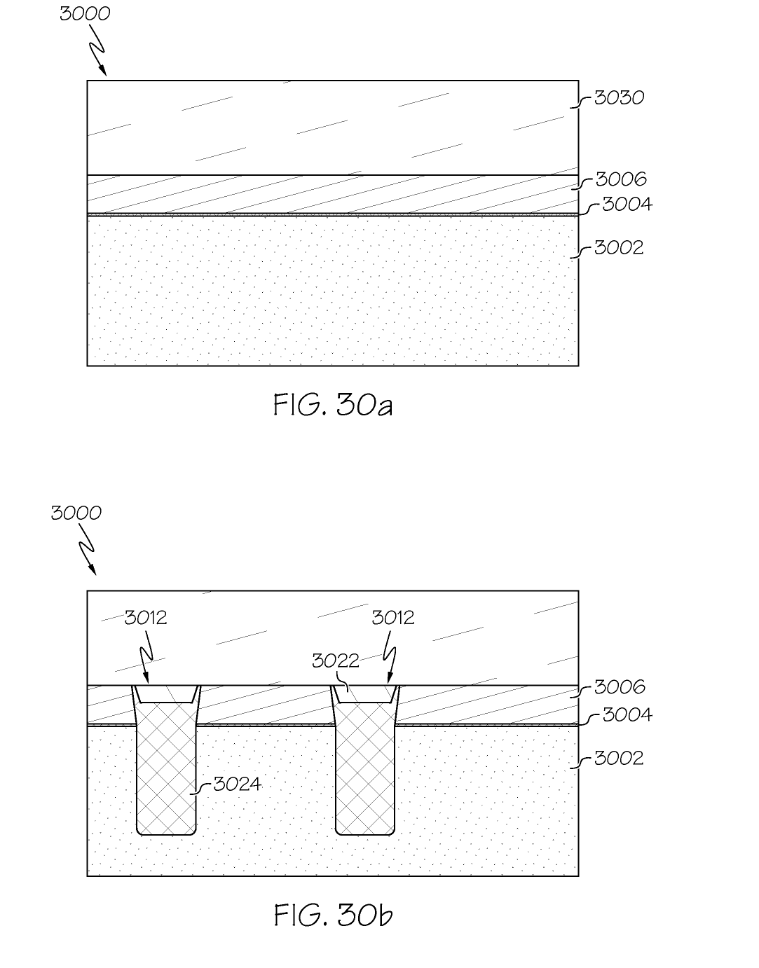

Finally, as shown in FIGS. 30(a)-(b), a mandrel layer 3030 is formed atop device 3000, including atop hardmask 3006 and HDP oxide 3022. In various embodiments, mandrel layer 3030 is formed over FinFET device 3000 prior to the formation of the fins, and may comprise an inorganic and/or dielectric material such as polycrystalline silicon or silicon oxide (SiOₓ) where x is a number greater than zero, silicon nitride (Si₃N₄), silicon oxynitride (SiON), or the like.

In various embodiments, design tools can be provided and configured to create the datasets used to pattern the semiconductor layers as described herein. For example, design tools can be used to form a set of fins from a substrate and form an opening through the set of fins, the opening oriented substantially perpendicular to an orientation of the set of fins. To accomplish this, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines, or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that approaches have been described for providing a narrow diffusion break in a FinFET device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method for forming a fin field effect transistor (FinFET) device, the method comprising:
forming a set of fins from a substrate; and
forming an opening through the set of fins, the opening oriented substantially perpendicular to an orientation of the set of fins.

2. The method according to claim 1, wherein the opening has a width of approximately 20 nanometers to 30 nanometers.

3. The method according to claim 1, further comprising:
forming a pad layer over the set of fins; and
forming a hardmask over the pad layer, wherein the opening is formed through the hardmask.

4. The method according to claim 3, further comprising:
removing the pad layer within the opening;
removing silicon from the set of fins within the opening; and
epitaxially growing a silicon layer within the opening.

5. The method according to claim 4, further comprising:
forming a high density plasma (HDP) oxide over the FinFET device;
removing the HDP oxide over the set of fins; and
recessing the HDP oxide within the opening to partially expose the set of fins.

6. The method according to claim 4, further comprising:
forming an inner spacer over the hardmask and within the opening;
patterning the inner spacer within the opening;
etching the silicon to extend the opening below the pad layer;
thermally oxidizing the FinFET device to widen the opening below the pad layer;
forming the HDP oxide over the FinFET device;
removing the HDP oxide and the hardmask over the set of fins; and
recessing a shallow trench insulation (STI) layer within the opening to partially expose the set of fins.

7. The method according to claim 6, the forming the inner spacer comprising an in-situ radical assisted deposition (iRAD) of oxide.

8. The method according to claim 1, further comprising forming a mandrel layer over the FinFET device prior to the formation of the set of fins.

9. A method for forming a narrow diffusion break in a fin field effect transistor (FinFET) device, the method comprising:
forming a set of fins from a substrate; and
forming an opening through the set of fins, the opening oriented substantially perpendicular to an orientation of the set of fins.

10. The method according to claim 9, wherein the opening has a width of approximately 20 nanometers to 30 nanometers.

11. The method according to claim 9, further comprising:
forming a pad layer over the set of fins; and
forming a hardmask over the pad layer, wherein the opening is formed through the hardmask.

12. The method according to claim 11, further comprising:
removing the pad layer within the opening;
removing silicon from the set of fins within the opening; and
epitaxially growing a silicon layer within the opening.

13. The method according to claim 12, further comprising:
forming a high density plasma (HDP) oxide over the FinFET device;
removing the HDP oxide over the set of fins; and
recessing the HDP oxide within the opening to partially expose the set of fins.

14. The method according to claim 13, further comprising:
forming an inner spacer over the hardmask and within the opening;
patterning the inner spacer within the opening;
etching the silicon to extend the opening below the pad layer;
thermally oxidizing the FinFET device to widen the opening below the pad layer;
forming the HDP oxide over the FinFET device;
removing the HDP oxide and the hardmask over the set of fins; and
recessing a shallow trench insulation (STI) layer within the opening to partially expose the set of fins.

15. The method according to claim 14, the forming the inner spacer comprising an in-situ radical assisted deposition (iRAD) of oxide.

16. The method according to claim 9, further comprising forming a mandrel layer over the FinFET device prior to the formation of the set of fins.

17. A fin field effect transistor (FinFET) device comprising:
a set of fins formed from a substrate; and
an opening formed through the set of fins, the opening oriented substantially perpendicular to an orientation of the set of fins.

18. The FinFET device according to claim 17, wherein the opening has a width of approximately 20 nanometers to 30 nanometers.

19. The FinFET device according to claim 17, wherein the opening is a substantially vertical slit.

20. The FinFET device according to claim 17, the opening comprising:
a silicon layer formed therein; and
a high density plasma (HDP) oxide formed over the silicon layer, wherein the HDP oxide is partially recessed to expose the set of fins.
